(19) United States
(12) Patent Application Publication
(10) Pub. No.: US 2025/0343091 A1
(43) Pub. Date: Nov. 6, 2025

(54) Integration of Liner in Passivation Stack

(71) Applicant: Wolfspeed, Inc., Durham, NC (US)

(72) Inventors: Shadi S. Sabri, Apex, NC (US); Neal Curtis Oldham, Apex, NC (US)

(21) Appl. No.: 18/656,059

(22) Filed: May 6, 2024

(51) Int. Cl. H01L 23/31; H01L 21/56; H01L 21/784; H01L 23/00; H01L 23/29; H01L 23/52

(52) U.S. Cl. CPC H01L 23/3192; H01L 21/561; H10D 89/013; H01L 23/291; H01L 23/293; H01L 23/52; H01L 24/32; H01L 24/45; H01L 24/48; H01L 2224/32245; H01L 2224/45124; H01L 2224/45147; H01L 2224/48091; H01L 2224/48225; H01L 2224/48245; H01L 2924/10253; H01L 2924/10272; H01L 2924/1033; H01L 2924/12032; H01L 2924/13064; H01L 2924/13091

(57) ABSTRACT

Power semiconductor devices and power semiconductor device packages are provided. In one example, a power semiconductor device package includes a submount and a semiconductor die on the submount. In some examples, the semiconductor die includes a metallization structure, a first passivation layer on the metallization structure, a buffer layer on the first passivation layer, a second passivation layer on the buffer layer, and a polyimide layer directly on the second passivation layer. In some examples, the second passivation layer includes the same material as the first passivation layer.

### FIELD

The present disclosure relates generally to semiconductor devices.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”). Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices.

Power semiconductor devices may be packaged into various semiconductor device packages, such as discrete semiconductor device packages and power modules. Power modules may include one or more power devices and other circuit components and can be used, for instance, to dynamically switch large amounts of power through various components, such as motors, inverters, generators, and the like.

Semiconductor devices may be fabricated from wide bandgap semiconductor materials, such as silicon carbide and/or Group III nitride-based semiconductor materials. The fabrication process for power semiconductor devices may require processing of wide bandgap semiconductor wafers, such as silicon carbide semiconductor wafers.

### SUMMARY

Aspects and advantages of embodiments of the present disclosure will be set forth in part in the following description, or can be learned from the description, or can be learned through practice of the embodiments.

In one aspect, the present disclosure provides an example power semiconductor device. In some implementations, the example power semiconductor device includes a semiconductor structure. In some implementations, the example power semiconductor device includes a metallization structure on the semiconductor structure. In some implementations, the example power semiconductor device includes a first passivation layer on the metallization structure, the first passivation having a first thickness. In some implementations, the example power semiconductor device includes a buffer layer on the first passivation layer. In some implementations, the example power semiconductor device includes a second passivation layer on the buffer layer, the second passivation layer comprising the same material as the first passivation layer, the second passivation layer having a second thickness that is different than the first thickness.

In another aspect, the present disclosure provides an example power semiconductor device package. In some implementations, the example power semiconductor device package includes a submount. In some implementations, the example power semiconductor device package includes a semiconductor die on the submount. In some implementations, the semiconductor die includes a metallization structure. In some implementations, the semiconductor die includes a first passivation layer on the metallization structure. In some implementations, the semiconductor die includes a buffer layer on the first passivation layer. In some implementations, the semiconductor die includes a second passivation layer on the buffer layer, the second passivation layer comprising the same material as the first passivation layer. In some implementations, the semiconductor die includes a polyimide layer directly on the second passivation layer.

In another aspect, the present disclosure provides an example method. In some implementations, the example method includes providing a semiconductor structure. In some implementations, the example method includes providing a metallization structure on the semiconductor structure. In some implementations, the example method includes providing a first passivation layer on the metallization structure, the first passivation layer having a first thickness. In some implementations, the example method includes providing a buffer layer on the first passivation layer. In some implementations, the example method includes providing a second passivation layer on the buffer layer, the second passivation layer comprising the same material as the first passivation layer, the second passivation layer having a second thickness that is different than the first thickness.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a plan view of an example semiconductor wafer having a plurality of semiconductor devices according to example embodiments of the present disclosure;

FIG. 2 depicts a plan view of an example semiconductor device of the example semiconductor wafer depicted in FIG. 1 according to example embodiments of the present disclosure;

FIG. 3 depicts a plan view of an example semiconductor device of the example semiconductor wafer depicted in FIG. 1 according to example embodiments of the present disclosure;

FIG. 4A depicts a plan view of an example semiconductor device according to example embodiments of the present disclosure;

FIG. 4B depicts a cross-sectional view of the example semiconductor device of FIG. 4A taken along the line A-A according to example embodiments of the present disclosure;

FIG. 5A depicts a plan view of an example semiconductor device according to example embodiments of the present disclosure;

FIG. 5B depicts a cross-sectional view of the example semiconductor device of FIG. 5A taken along the line A-A according to example embodiments of the present disclosure;

FIG. 6A depicts a plan view of an example semiconductor device according to example embodiments of the present disclosure;

FIG. 6B depicts a cross-sectional view of the example semiconductor device of FIG. 6A taken along the line A-A according to example embodiments of the present disclosure;

FIG. 7 depicts a flow chart diagram of an example method according to example embodiments of the present disclosure;

FIG. 8 depicts an example semiconductor package of a semiconductor device according to example embodiments of the present disclosure; and

FIG. 9 depicts an example semiconductor package of a semiconductor device according to example embodiments of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Semiconductor device packages (e.g., discrete semiconductor device packages and power modules) have been developed that include a semiconductor die, such as a metal-oxide-semiconductor field-effect transistor (MOSFET), a Schottky diode, and/or a high electron mobility transistor (HEMT) device. Semiconductor device packages with MOSFETs may be employed in a variety of applications to enable higher switching frequencies along with reduced associated losses, higher blocking voltages, and improved avalanche capabilities. Example applications may include high performance industrial power supplies, server/telecom power, electric vehicle charging systems, energy storage systems, uninterruptible power supplies, high-voltage DC/DC converters, electric vehicles, and battery management systems. Semiconductor device packages with Schottky diodes and/or HEMT devices may be employed in many of the same high-performance power applications described above for MOSFETs, sometimes in systems that also include discrete power packages of MOSFETs.

Example aspects of the present disclosure are directed to semiconductor devices and to semiconductor device packages for use in semiconductor applications and other electronic applications. It should be understood that the terms “semiconductor device package” and “semiconductor package” may be used interchangeably. In some examples, semiconductor device packages may include one or more semiconductor die. The one or more semiconductor die may include a wide bandgap semiconductor material. A wide bandgap semiconductor has a band gap greater than about 1.40 eV, such as silicon carbide and/or a Group-III nitride (e.g., gallium nitride).

In some examples, the one or more semiconductor die may include one or more semiconductor devices, such as transistors, diodes, and/or thyristors. For instance, in some examples, the one or more semiconductor die may include a MOSFET, such as a silicon carbide-based MOSFET. Additionally and/or alternatively, in some examples, the one or more semiconductor die may include a Schottky diode, such as a silicon carbide-based Schottky diode. Additionally and/or alternatively, in some examples, the one or more semiconductor die may include a HEMT device, such as a Group-III nitride-based HEMT device.

It should be understood that aspects of the present disclosure are discussed with reference to silicon carbide-based MOSFET devices for purposes of illustration and discussion. Those having ordinary skill in the art, using the disclosures provided herein, will understand that the power semiconductor package of the present disclosure may include other power semiconductor devices without deviating from the scope of the present disclosure, such as diodes (e.g., Schottky diodes, PiN diodes, etc.), insulated gate bipolar transistors, HEMTs, or other devices.

In some semiconductor packages, the one or more semiconductor die may be attached to a submount (e.g., lead frame) by a die-attach material between the one or more semiconductor die and the submount. For instance, in some examples, a die-attach material may be deposited on the submount, and the semiconductor die (or other component) may be placed on the die-attach material, and the die-attach material may be subjected to bonding or a bonding process (e.g., sintering) to secure the semiconductor die (or other component) to the die-attach material. Various types of die-attach material may be used to bond the one or more semiconductor die to the submount such as, for instance, metal sintering die-attach (e.g., silver (Ag) or copper (Cu)) and conductive adhesive die-attach. Additionally and/or alternatively, in some examples, the semiconductor package may use wire bond(s) (e.g., aluminum wire bond(s)) for interconnection between portions of the one or more semiconductor die (e.g., a gate contact) and the package (e.g., lead frame).

The semiconductor package may further include a housing in which the one or more semiconductor die may be arranged. The semiconductor package may also include one or more electrical leads extending from the housing. More particularly, in some examples, the housing may be an encapsulating portion (e.g., epoxy mold compound (EMC)) formed around at least a portion of the submount and the one or more semiconductor die.

The one or more semiconductor die may further include one or more metallization structures. A “metallization structure” is any layer, structure, or other portion of a semiconductor die that incorporates a metal and/or a metal alloy for thermal and/or electrical conduction. As used herein, the term “alloy” refers to a mixture of metal elements. Metallization structures in a semiconductor device may be used, for instance, to provide an electrically conductive and/or thermally conductive connection to the one or more semiconductor die. The metallization structure may include, for instance, one or more electrodes, contacts, interconnections, bonding pads, backside layers, metal layers, or metal coatings of the semiconductor device on the semiconductor die.

Power semiconductor devices and packages may further include one or more passivation layers on the one or more semiconductor die, such as a silicon nitride and/or polyimide passivation layer(s). Passivation layers may be used to protect exposed layers of the power semiconductor device and package, such as underlaying dielectrics, overlayer metals, overlayer metal edges, and/or the like. More particularly, passivation layers may protect such materials from diffusion of contaminants and humidity ingress. Moreover, passivation layers may buffer some thermomechanical stress exerted by both underlaying and overlaying layers. In some instances, cracks in the passivation layer(s) may result from thermomechanical stress to a semiconductor die surface during different reliability tests, such as thermal cycling (TC) tests, and/or during operation of the power semiconductor device. In such instances, cracked or otherwise damaged passivation layers cease to perform its protection function as an effective barrier(s).

For instance, some passivation layers include, e.g., polyimide, silicon nitride (SiN_{X}) and/or silicon oxide (SiO_{X}). During thermal cycling (TC) tests, epoxy mold compounds (EMCs) may induce a shear stress to such passivation layers, which may subsequently be transferred to underlying layers and structures, such as the metallization structures, semiconductor die, submount, and the like. Furthermore, the shear stress induced in the passivation layer may concentrate at an interface with the underlying layers and structures, such as at the edges of the metallization structures and/or semiconductor die, leading to deformation, delamination, and/or ratcheting of metallization structures and semiconductor die. For instance, the thermomechanical induced shear stress may build up and cascade with each thermal cycle, which may result in plastic deformation of the metallization structures due to their relatively low yield strength compared to the induced shear stress. This phenomenon—which may be referred to as “ratcheting”—may result in glacial moving and/or delamination of the metallization structures, as well as cracking of the passivation layer.

To further protect against the above-described thermomechanical stress-related failures, some power semiconductor devices and packages may include a buffer layer between the metallization structures and the passivation layer(s). As will be described in greater detail below, in some examples, power semiconductor device packages of the present disclosure may include an oxide buffer layer, which reduces cracking in the passivation layer(s) and improves overall robustness and ruggedness of the semiconductor die for thermomechanical stress and humidity. However, in some examples, new reliability challenges may be introduced at an interface between the (e.g., oxide) buffer layer and the metallization structure(s), such as extrinsic dielectric breakdown caused by metal diffusion (e.g., copper (Cu) diffusion, etc.) and/or the like.

Accordingly, example aspects of the present disclosure are directed to power semiconductor devices and power semiconductor device packages having a multi-layered passivation stack that addresses the aforementioned reliability issues. More particularly, a power semiconductor device of the present disclosure may include a semiconductor structure, a metallization structure, and a multi-layered passivation stack on the metallization structure. For instance, as will be described in greater detail below, an example power semiconductor device may include a first passivation layer on the metallization structure, a buffer layer on the first passivation layer, and a second passivation layer on the buffer layer that includes the same material as the first passivation layer. In this manner, the first passivation layer may act as a passivation liner between the buffer layer and the metallization structure.

The first passivation layer may have a first thickness, and the second passivation layer may have a second thickness. In some examples, the second thickness may be different from the first thickness. In some examples, the first passivation layer may have a reduced thickness relative to the second passivation layer. Put differently, in some examples, the second thickness may be greater than the first thickness. By way of non-limiting example, the second thickness may be at least 1.5 times thicker than the first thickness, such as at least 3 times thicker than the first thickness.

In some examples, the first passivation layer and the second passivation layer may include a nitride, such as silicon nitride, and the buffer layer may be an oxide buffer layer, such as a silicon dioxide (SiO₂) buffer layer, a hafnium dioxide (HfO₂) buffer layer, a zirconium dioxide (ZrO₂) buffer layer, an aluminum oxide (Al₂O₃) buffer layer, and/or the like. In this manner, the buffer layer may be a stress absorbing layer for the second passivation layer, and the first passivation layer may reduce metal diffusion along an interface between the buffer layer and the metallization structure.

Aspects of the present disclosure provide a number of technical effects and benefits. For instance, example passivation stacks of the present disclosure include a buffer layer that provides for increased robustness and ruggedness for thermomechanical stress and humidity. Moreover, by including a thin passivation layer between the metallization structure(s) and the buffer layer, example passivation stacks of the present disclosure provide a seal between the metallization structure(s) and the buffer layer which, in turn, reduces metal diffusion at the interface between the passivation stack and the metallization structure(s). In this manner, example power semiconductor devices and packages of the present disclosure provide for reduced susceptibility to thermomechanical stress-induced failures (e.g., cracking, deformation, delamination, ratcheting, etc.) and other diffusion-related failures, which increases the overall structural robustness and reliability of the power semiconductor device as a whole.

It will be understood that, although the terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present, except in some examples an attach material (e.g., die-attach material, solder, paste, adhesive, sintered material or other material may be present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present, except in some examples an attach material (e.g., die-attach material, solder, paste, adhesive, sintered material or other material may be present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments of the disclosure. The thickness of layers and regions in the drawings may be exaggerated for clarity. Additionally, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to silicon carbide-based semiconductor structures, such as silicon carbide-based MOSFETs. Those of ordinary skill in the art, using the disclosures provided herein, will understand that the power semiconductor packages according to example embodiments of the present disclosure may be used with any semiconductor material, such as other wide band gap semiconductor materials, without deviating from the scope of the present disclosure. Example wide band gap semiconductor materials include silicon carbide (e.g., 2.996 eV band gap for alpha silicon carbide at room temperature) and the Group III-nitrides (e.g., 3.36 eV band gap for gallium nitride at room temperature).

In the drawings and specification, there have been disclosed typical embodiments and, although specific terms are employed, they are used in a generic and descriptive sense only and not for purposes of limitation of the scope set forth in the following claims.

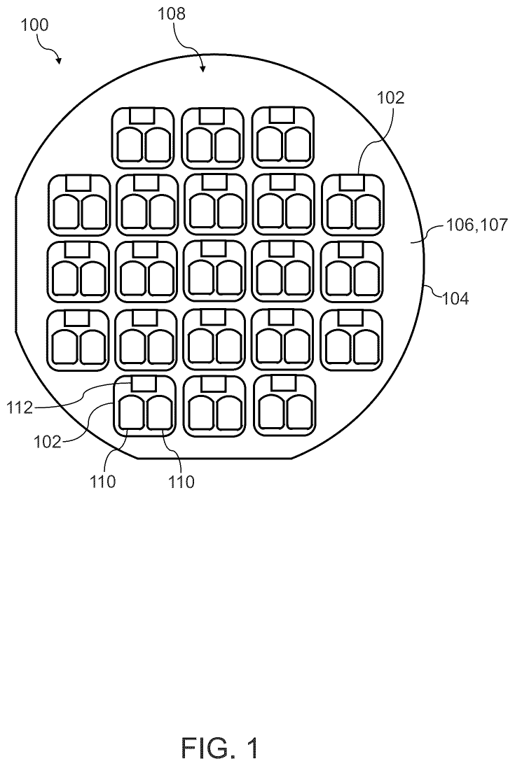

FIG. 1 depicts a plan view of a top side of an example semiconductor wafer 100 according to example embodiments of the present disclosure. The semiconductor wafer 100 may serve as the foundation for manufacturing a plurality of semiconductor devices, such as integrated circuits (ICs) and/or other electronic components. It should be understood that FIG. 1 is intended to represent structures for purposes of identification and description and is not intended to represent the structures to physical scale.

As shown, the semiconductor wafer 100 may include a plurality of semiconductor devices 102 provided therein. The semiconductor devices 102 may be provided in rows and columns and may be spaced apart from each other such that the semiconductor wafer 100 may later be subjected to a singulation process (e.g., diced) to separate the individual semiconductor devices 102 for packaging and testing.

The semiconductor wafer 100 may be a thin, disc-shaped sheet of semiconductor material, such as silicon (Si), silicon carbide (SiC), gallium nitride (GaN), and/or the like. The semiconductor wafer 100 may include a semiconductor structure with other material layers, such as protective (e.g., passivation) layers and/or metal layers, provided thereon. More particularly, the semiconductor wafer 100 may include a semiconductor substrate 104. In some examples, the semiconductor wafer 100 may include one or more epitaxial layers 106, which may be a single-crystal semiconductor layer grown on a top side of the substrate 104. In some examples, the semiconductor wafer 100 may include one or more passivation layers 107 having any suitable passivation material, such as one or more silicon nitride layers, one or more polymer layers, and/or the like.

The semiconductor substrate 104 may include a semiconductor material, such as a wide bandgap semiconductor material. By way of non-limiting example, the semiconductor substrate 104 may be a silicon (Si) substrate, a silicon carbide (SiC) substrate, a Group III-nitride (e.g., gallium nitride (GaN)) substrate, a sapphire substrate, and/or other suitable substrates. In some examples, the semiconductor substrate 104 may be a SiC substrate that may include, for example, the 4H polytype of SiC or may be the 3C, 6H, and/or 15R polytypes of SiC. Other semiconductor layers (e.g., polysilicon gate layers), protective layers (e.g., passivation layers), insulating layers, and/or metal layers may be provided on the semiconductor substrate 104 to form the plurality of semiconductor devices 102. In this manner, the semiconductor substrate 104 may be a semiconductor structure. As used herein, a “semiconductor structure” refers to a structure having one or more semiconductor layers, such as semiconductor substrates and/or semiconductor epitaxial layers.

As noted above, the semiconductor wafer 100 may be subjected to wafer-level processing and diced to form a plurality of semiconductor die 108 having one or more of the plurality of semiconductor devices 102. More particularly, each semiconductor device 102 may be spaced apart on the semiconductor wafer 100 and may include, for instance, a silicon carbide-based metal-oxide-semiconductor field-effect transistor (MOSFET), a silicon carbide-based Schottky diode, a Group-III nitride-based high electron mobility transistor (HEMT) device, and/or the like. The semiconductor wafer 100 may be cut and/or diced (e.g., using a wire saw and/or a laser) along a portion of the semiconductor wafer 100 that runs between each of the semiconductor devices 102 such that each individual cut piece becomes a semiconductor die 108 that is later packaged in a semiconductor device package (e.g., discrete semiconductor device package, power module, etc.).

In some examples, such as that depicted in FIG. 1, the semiconductor devices 102 may include vertical structures (e.g., vertical semiconductor device units) such that each semiconductor device 102 is a vertical semiconductor device. More particularly, each semiconductor device 102 may include at least one electrode (e.g., source electrode, gate electrode, drain electrode for a power MOSFET device) on each major side (e.g., top side, bottom side) of the semiconductor structure. Additionally and/or alternatively, in other examples (not shown), the semiconductor devices 102 may include lateral structures (e.g., lateral semiconductor device units) such that each semiconductor device 102 is a lateral semiconductor device having the electrodes on the same major side of the semiconductor structure. Furthermore, metal layer structures (e.g., metallization layers and/or metallization structures) may be provided on each side of the semiconductor devices 102 to form electrodes for the semiconductor devices 102 (e.g., source electrode 110, gate electrode 112, drain electrode (not shown)). It should be understood that the terms “metal layer structure,” “metallization layer,” and/or “metallization structure” may be used interchangeably.

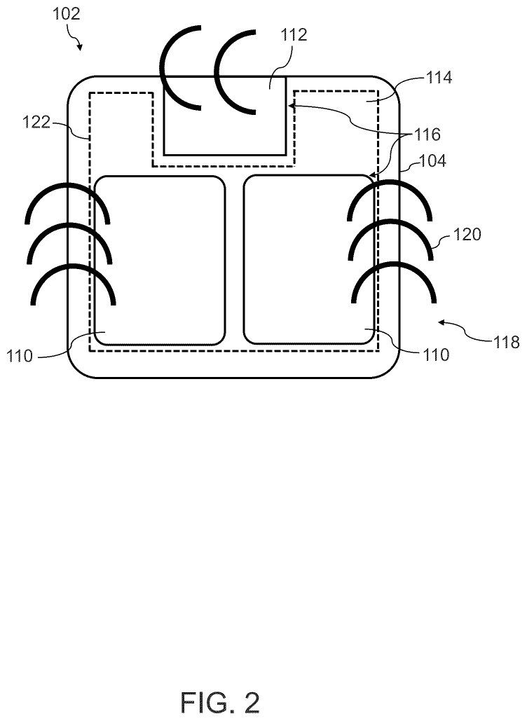

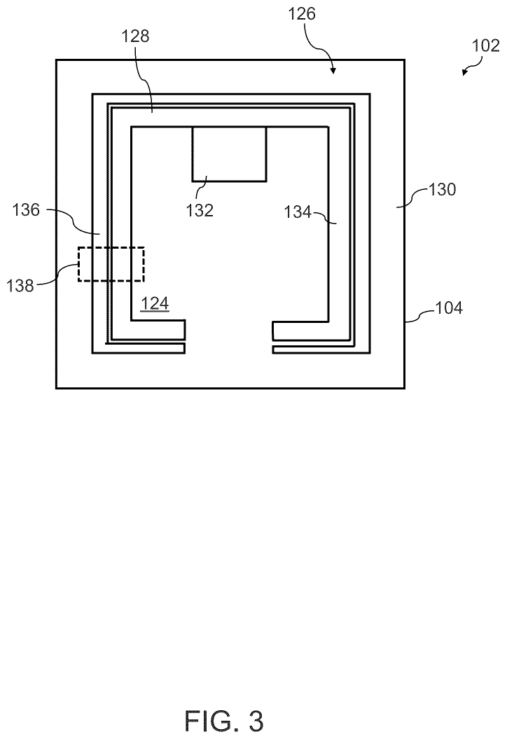

FIGS. 2-3 depict plan views of one of the example power semiconductor devices 102 on the example semiconductor wafer 100 depicted in FIG. 1 according to example embodiments of the present disclosure. More particularly, FIG. 2 depicts a plan view of the example power semiconductor device 102 with source metallization (e.g., source metal pattern 122), and FIG. 3 depicts a plan view of the example semiconductor device 102 of FIG. 2 with the source metallization (e.g., source metal pattern 122) removed. It should be understood that, in the description below, it is assumed that the power semiconductor device 102 is an n-type power MOSFET. However, those having ordinary skill in the art, using the disclosures provided herein, will understand that aspects of the present disclosure may be implemented in a p-type power MOSFET or other semiconductor device (e.g., IGBT, Schottky diode, etc.) without deviating from the scope of the present disclosure. Furthermore, it should be understood that FIGS. 2-3 are intended to represent structures for purposes of identification and description and are not intended to represent the structures to physical scale.

As shown in FIG. 2, the semiconductor device 102 may include a semiconductor structure, such as the semiconductor substrate 104. The semiconductor device 102 may further include a protective layer 114 that covers a substantial portion of the top side of the semiconductor device 102. The protective layer 114 may be formed from a dielectric material, such as, by way of non-limiting example, polyamide. Various bond pads and/or contacts may be exposed through openings 116 in the protective layer 114. More particularly, the contacts may include a gate contact (e.g., gate electrode 112) and one or more source contacts (e.g., source electrodes 110). While not visible in FIG. 2, the semiconductor device 102 may include a drain contact (e.g., drain electrode 118) on the bottom side of the semiconductor device 102. The contacts (e.g., source electrodes 110, gate electrode 112, drain electrode 118) may be formed of a metal (e.g., aluminum) and/or a metal alloy (e.g., an aluminum-copper (AlCu) alloy). The contacts may be coupled to terminals in a power semiconductor package to provide a gate terminal, source terminal, and drain terminal (respectively) for the power semiconductor device 102. In some examples, the contacts (e.g., source electrodes 110, gate electrode 112, drain electrode 118) may be coupled to the respective terminals via wire bonds 120, which may be attached using any suitable technique (e.g., thermos-compression, soldering, etc.).

As will be discussed in greater detail below, the contacts (e.g., source electrodes 110, gate electrode 112, drain electrode 118) may contact a semiconductor structure of the semiconductor device 102. For instance, the source electrodes 110 may contact lower portions of a source metal pattern 122 that extends across much of the upper surface of the semiconductor device 102 (e.g., all but the portion of the upper surface of the semiconductor device 102 occupied by the gate electrode 112). In some examples, the source electrodes 110 may include portions of the source metal pattern 122 that are exposed by the openings 116 in the protective layer 114. Wire bonds 120 may be used to connect the source electrodes 110 and the gate electrode 112 to external voltage sources (not shown), such as terminals of other circuit elements.

As shown in FIG. 3, the semiconductor structure (e.g., semiconductor substrate 104) of the semiconductor device 102 may include an active region 124 and an inactive region 126. As used herein, the active region 124 refers to an area of the semiconductor device 102 that includes operable transistors (e.g., unit cell devices), while the inactive region 126 refers to an area of the semiconductor device 102 that does not include such operable transistors. More particularly, in some examples, the active region 124 may generally correspond to the area under the source metal pattern 122 (FIG. 2). The semiconductor device 102 may include a plurality of unit cell devices (not shown) in the active region 124. For instance, each unit cell device may be a wide bandgap semiconductor, such as, by way of non-limiting example, a silicon carbide-based MOSFET, a silicon carbide-based Schottky diode, a Group-III nitride-based HEMT device, and/or the like.

Furthermore, the inactive region 126 may include a gate structure 128 and an edge termination region 130. More particularly, in some examples, the inactive region 126 may be under the gate structure 128. The edge termination region 130 of the inactive region 126 may extend around a periphery of the semiconductor device 102 and may include one or more termination structures such as, by way of non-limiting example, guard rings, a junction termination extension, and/or the like. The edge termination structures may reduce electric field crowding that may occur around a peripheral edge of the semiconductor device 102 by spreading out the electric fields along the periphery of the semiconductor device 102. In some examples, the edge termination structures may serve to increase the reverse blocking voltage at which a phenomenon known as “avalanche breakdown” occurs, where an increasing electric field results in a runaway generation of charge carriers within the semiconductor device 102, thereby resulting in a sharp increase in current that may ultimately damage and/or destroy the semiconductor device 102.

As shown in FIG. 3, the gate structure 128 (e.g., gate electrode pattern) may include a gate pad 132 and one or more metallization structures, such as a plurality of gate fingers (not shown) and one or more peripheral gate runners 134 (e.g., gate buses). The gate runners 134 may electrically couple the gate fingers to the gate pad 132. In some examples, the gate pad 132 may be underneath the gate electrode 112 (FIG. 2). The gate runners 134 may be located about or around at least a part of the peripheral portion of the semiconductor device 102 in the inactive region 126. The gate fingers (not shown) may extend across the active region 124. An insulating layer (not shown) may cover the gate fingers and the gate runner(s) 134. The source metal pattern 122 (FIG. 2) may be provided over the gate fingers and insulating layer, with the source electrodes 110 (FIG. 2) contacting corresponding source regions in the semiconductor structure via openings between the gate fingers.

The semiconductor device 102 may further include one or more peripheral source runners 136 located adjacent to the one or more peripheral gate runners 134. The source runner 136 may be a metallization structure that is coupled (e.g., conductively coupled) to a source pad and/or a source terminal associated with the semiconductor device 102. More particularly, in some examples, the semiconductor device 102 may include a source pad and/or a source terminal that, together with the source runner 136, forms a source structure for the semiconductor device 102. As shown, the source runner 136 may be between the gate runner 134 and a peripheral edge of the semiconductor device 102, such as between the gate runner 134 and the edge termination region 130.

As will be discussed in greater detail below, in some examples, the gate runners 134 may be on a field insulating layer of the semiconductor device 102. For instance, in some examples, the gate runners 134 may be on an oxide layer, such as a SiO_{X} layer, which may in turn be on a p-well region of the inactive region 126.

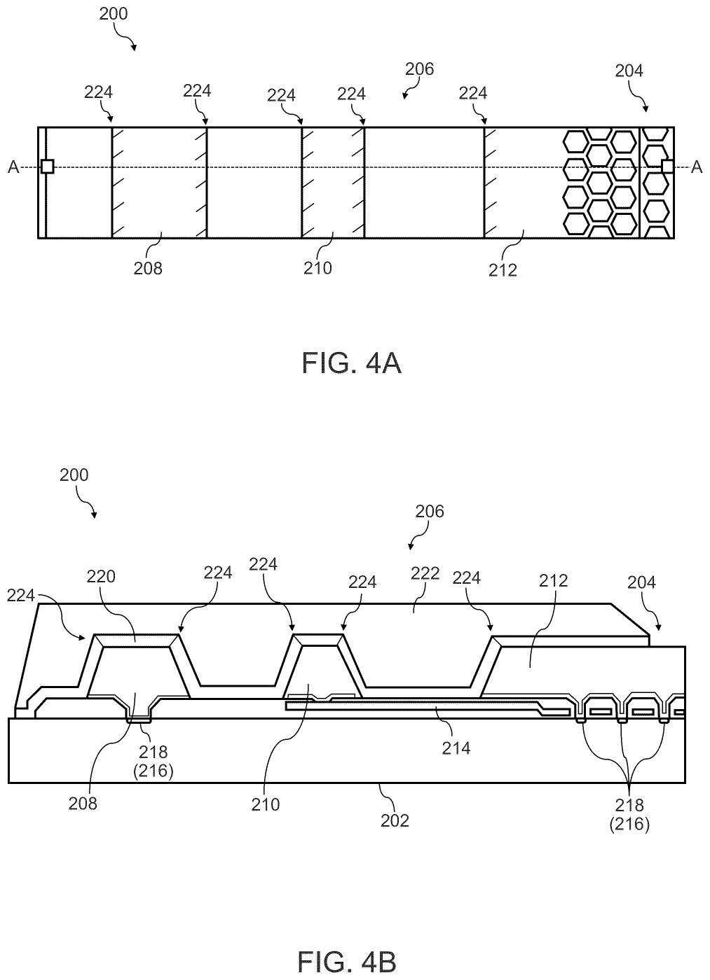

FIGS. 4A-4B depict an example semiconductor device 200 according to example embodiments of the present disclosure. It should be understood that the example semiconductor device 200 may be similar to the example semiconductor device 102 described above with reference to FIGS. 1-3. For instance, FIG. 4A depicts a close-up plan view of the semiconductor device 200 at a location on the semiconductor device 200 that corresponds to a location on the semiconductor device 102 designated by box 138 (FIG. 3). Furthermore, FIG. 4B depicts a cross-sectional view of the example semiconductor device 200 taken along the line A-A of FIG. 4A. It should be understood that FIGS. 4A-4B are intended to represent structures for purposes of identification and description and are not intended to represent the structures to physical scale.

As noted above, the semiconductor device 200 may be similar to the semiconductor device 102 (FIGS. 1-3). For instance, as shown, the semiconductor device 200 may include a semiconductor structure 202 having an active region 204 and an inactive region 206. The active region 204 is represented as a plurality of hexagonal cells. However, other suitable geometries of the unit cells in the active region 204 may be implemented without deviating from the scope of the present disclosure.

In some examples, the semiconductor structure 202 may be similar to the semiconductor substrate 104 and/or the semiconductor die 108 described above with reference to FIGS. 1-3. The semiconductor structure 202 may include a wide bandgap semiconductor, such as silicon carbide, a Group III-nitride, and/or the like. In this way, the semiconductor device 200 may be a power semiconductor device 200, such as, by way of non-limiting example, a silicon carbide-based MOSFET, a silicon carbide-based Schottky diode, a Group-III nitride-based HEMT device, and/or the like.

The semiconductor device 200 may include one or more metallization structures on the semiconductor structure 202. More particularly, as shown, the semiconductor device 200 may include a first metallization structure 208 and a second metallization structure 210. As shown, the first metallization structure 208 and the second metallization structure 210 may be on the inactive region 206 of the semiconductor structure 202. As noted above, the first metallization structure 208 and the second metallization structure 210 may include any suitable material, such as a metal (e.g., aluminum) and/or a metal alloy (e.g., an aluminum-copper alloy). Furthermore, the first metallization structure 208 and the second metallization structure 210 may be any suitable metallization structure for the semiconductor device 200, such as, by way of non-limiting example, an electrode, an interconnect, a runner, a finger, and/or the like.

In some examples, the first metallization structure 208 and the second metallization structure 210 may be spaced apart from one another and may be located around at least a part of a peripheral portion of the semiconductor device 200. Hence, the first metallization structure 208 and the second metallization structure 210 may each be peripheral runner structures for the semiconductor device 200. For instance, in the example depicted in FIGS. 4A-4B, the first metallization structure 208 may be a peripheral source runner for the semiconductor device 200 (e.g., source runner 136 (FIGS. 1-3)) and the second metallization structure 210 may be a peripheral gate runner for the semiconductor device 200 (e.g., gate runner 134 (FIGS. 1-3)).

The semiconductor device 200 may further include additional metallization structures on the semiconductor structure 202, such as a source electrode and/or a gate electrode (not shown). It should be understood that the additional metallization structures in the active region 204 may be formed from similar materials (e.g., metal, metal alloys, etc.) as the first metallization structure 208 and the second metallization structure 210.

More particularly, as shown, the semiconductor device 200 may include a source pad 212 and a gate pad (not shown) (e.g., gate pad 132 (FIGS. 1-3)) that are partially on both the active region 204 and the inactive region 206 of the semiconductor structure 202. In some examples, the first metallization structure 208 and the source pad 212 may form a source structure for the semiconductor device 200, and the second metallization structure 210 and the gate pad (not shown) may form a gate structure for the semiconductor device 200. Furthermore, in some examples, the gate structure may further include a gate polysilicon layer 214 (e.g., gate finger) between the second metallization structure 210 and the semiconductor structure 202. The gate polysilicon layer 214 may be formed using a suitable deposition process. In some examples, the gate polysilicon layer 214 may be formed using a chemical vapor deposition (CVD) process, a physical vapor deposition (PVD) process, a sputtering process, an atomic layer deposition (ALD) process, or other suitable deposition process.

In some examples, the semiconductor device 200 may include one or more conductive layers, such as silicide layers 216, on the semiconductor structure 202 that, together with the corresponding metallization structure (e.g., first metallization structure 208, source pad 212), form ohmic contacts 218 for the semiconductor device 200.

The semiconductor device 200 may include one or more passivation layers on the semiconductor structure 202. For instance, as shown in FIG. 4B, the semiconductor device 200 may include a passivation layer 220 that extends across the inactive region 206 and at least partially overlaps the active region 204. In some examples, the passivation layer 220 may include a nitride, such as silicon nitride (SiN_{X}) and/or the like. The semiconductor device 200 may further include additional passivation layers, such as passivation layer 222, on the passivation layer 220. In some examples, the passivation layer 222 may include a dielectric material, such as a polymer, polyimide, silicon oxide (SiO_{X}), and/or the like.

As described above, the passivation layers 220, 222 may be used to protect underlying semiconductor structures of the semiconductor device 200 (e.g., first metallization structure 208, second metallization structure 210, source pad 212, semiconductor structure 202, etc.) from, for instance, contaminant diffusion, humidity ingress, thermomechanical stress, and/or the like. However, in some instances, one or more cracks 224 may form in the passivation layers 220, 222 due to thermomechanical stress resulting from operation of the semiconductor device 200 and/or reliability tests (e.g., thermal cycling (TC) tests) performed on the semiconductor device 200. In such instances, due to the cracks 224, the passivation layers 220, 222 may provide inadequate protection to the underlaying layers and overlaying layers of the semiconductor device 200, which may cascade and ultimately result in a variety of thermomechanical stress-induced failures in the semiconductor device 200.

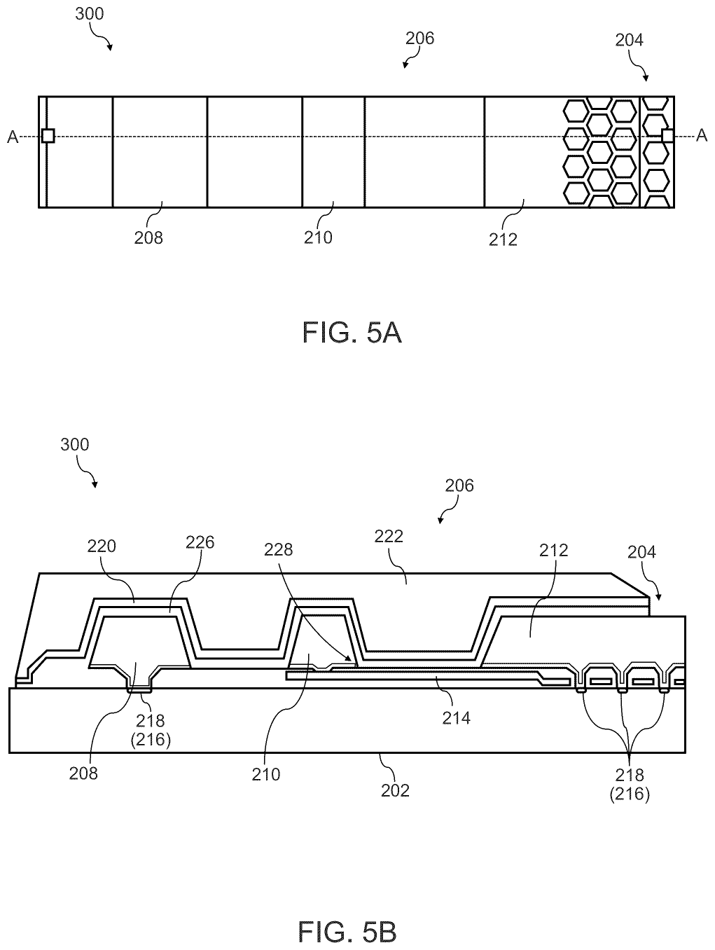

Some semiconductor devices may include additional protective layers and/or structures to absorb excess thermomechanical stress and, thereby, protect against the above-described thermomechanical stress-related failures. As one illustrative example, FIGS. 5A-5B depict an example semiconductor device 300 according to example embodiments of the present disclosure. More particularly, FIG. 5A depicts a close-up plan view of the semiconductor device 300 at the same location depicted in FIG. 4A with respect to the semiconductor device 200. Likewise, FIG. 5B depicts a cross-sectional view of the semiconductor device 300 taken along the line A-A of FIG. 5A. It should be understood that FIGS. 5A-5B are intended to represent structures for purposes of identification and description and are not intended to represent the structures to physical scale.

The semiconductor device 300 may be similar to the semiconductor device 200 depicted in, and discussed with reference to, FIGS. 4A-4B. However, in contrast to the semiconductor device 200, the semiconductor device 300 may include a buffer layer 226 between the metallization structures (e.g., first metallization structure 208, second metallization structure 210, source pad 212, etc.) and the passivation layers 220, 222. In some examples, the buffer layer 226 may be an oxide buffer layer. For instance, in some examples, the buffer layer 226 may include a silicon oxide (SiO_{X}), such as silicon dioxide (SiO₂). Additionally and/or alternatively, in some examples, the buffer layer 226 may include other oxides, such as hafnium dioxide (HfO₂), zirconium dioxide (ZrO₂), aluminum oxide (Al₂O₃), and/or the like.

The buffer layer 226 may be a stress absorbing layer for the passivation layers 220, 222 and other semiconductor structures of the semiconductor device 300 (e.g., first metallization structure 208, second metallization structure 210, source pad 212, semiconductor structure 202, etc.). In this manner, the buffer layer 226 may reduce cracking in the passivation layers 220, 222 and may increase the overall robustness and ruggedness of the semiconductor device 300 (relative to the semiconductor device 200). As noted above, the buffer layer 226 may include an oxide, such as silicon dioxide (SiO₂), hafnium dioxide (HfO₂), zirconium dioxide (ZrO₂), aluminum oxide (Al₂O₃), and/or the like, and the second metallization structure 210 may include an aluminum alloy, such as an aluminum-copper (AlCu) alloy. However, in some examples, the buffer layer 226 may lead to metal diffusion (e.g., copper (Cu) diffusion) towards other areas of the semiconductor device 300.

Accordingly, example aspects of the present disclosure are directed to a power semiconductor device and power semiconductor device package having a multi-layered passivation stack that protects against both the aforementioned thermomechanical stress-related issues (discussed above with reference to FIGS. 4A-4B) and the aforementioned diffusion-related issues (discussed above with reference to FIGS. 5A-5B).

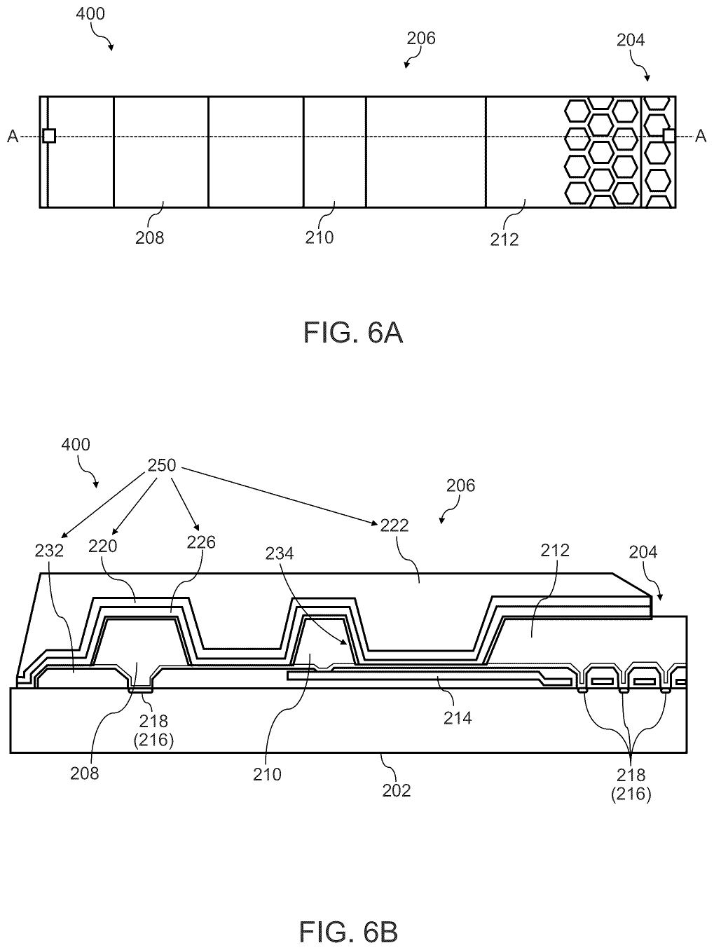

FIGS. 6A-6B depict an example semiconductor device 400 according to example embodiments of the present disclosure. More particularly, FIG. 6A depicts a close-up plan view of the semiconductor device 400 at the same location depicted in FIG. 5A with respect to the semiconductor device 300. Likewise, FIG. 6B depicts a cross-sectional view of the semiconductor device 400 taken along the line A-A of FIG. 6B. It should be understood that FIGS. 6A-6B are intended to represent structures for purposes of identification and description and are not intended to represent the structures to physical scale.

The semiconductor device 400 may be similar to any of the semiconductor devices discussed herein, such as the semiconductor device 102 (FIGS. 1-3), the semiconductor device 200 (FIGS. 4A-4B), and/or the semiconductor device 300 (FIGS. 5A-5B). However, the semiconductor device 400 may include a multi-layered passivation stack 250 that provides for increased structural robustness and ruggedness to humidity and thermomechanical stress, while also reducing metal and/or other contaminant diffusion at the metallization interfaces.

More particularly, in addition to the passivation layers 220, 222 and the buffer layer 226, the passivation stack 250 may further include an additional passivation layer 232. As shown in FIG. 6B, the passivation stack 250 may extend across the inactive region 206 of the semiconductor structure 202 and may at least partially overlap the active region 204 of the semiconductor structure 202. Hereinafter, for ease of discussion, the passivation layer 232 will be referred to as “first passivation layer 232,” the passivation layer 220 will be referred to as “second passivation layer 220,” and the passivation layer 222 will be referred to as “third passivation layer 222.”

As shown in FIG. 6B, the semiconductor device 400 may include the first passivation layer 232 on the one or more metallization structures (e.g., first metallization structure 208, second metallization structure 210, source pad 212, etc.). For instance, in some examples, at least a portion of the first passivation layer 232 directly contacts the one or more metallization structures. The semiconductor device 400 may further include the buffer layer 226 on the first passivation layer 232. In this way, the first passivation layer 232 may form a seal between the buffer layer 226 and the one or more metallization structures, thereby reducing metal diffusion along an interface (e.g., interface 234) between the metallization structures and the buffer layer 226.

The semiconductor device 400 may further include the second passivation layer 220 on the buffer layer 226. In some examples, the second passivation layer 220 may include the same material as the first passivation layer 232, such as a nitride (e.g., silicon nitride (SiN_{X})) and/or the like. Furthermore, in some examples, the first passivation layer 232, the buffer layer 226, and the second passivation layer 220 may form the passivation stack 250. Additionally and/or alternatively, in some examples, the semiconductor device 400 may further include the third passivation layer 222 on the second passivation layer 220. In such examples, the first passivation layer 232, the buffer layer 226, the second passivation layer 220, and the third passivation layer 222 may form the passivation stack 250. In some examples, the third passivation layer 222 may directly contact the second passivation layer 220. For instance, in some examples, the third passivation layer 222 may be a polyimide layer and may be directly on the second passivation layer 220.

As shown, the first passivation layer 232 may have a uniform thickness across at least a portion of a width of the semiconductor device 400. Additionally and/or alternatively, in other examples, the first passivation layer 232 may have a varied thickness across at least a portion of the width of the semiconductor device 400. By way of non-limiting example, the first passivation layer 232 may have a thickness in a range of about 100 angstroms (Å) to about 2 kiloangstroms (kÅ).

Furthermore, in some examples, the first passivation layer 232 may have a lesser thickness relative to the second passivation layer 220. For instance, the first passivation layer 232 may have a first thickness T₁, and the second passivation layer 220 may have a second thickness T₂ that is different than the first thickness T₁. In some examples, the second thickness T₂ may be greater than the first thickness T₁. By way of non-limiting example, the second thickness T₂ may be at least 1.5 times thicker than the first thickness T₁, such as at least 3 times thicker than the first thickness T₁, such as at least 5 times thicker than the first thickness T₁.

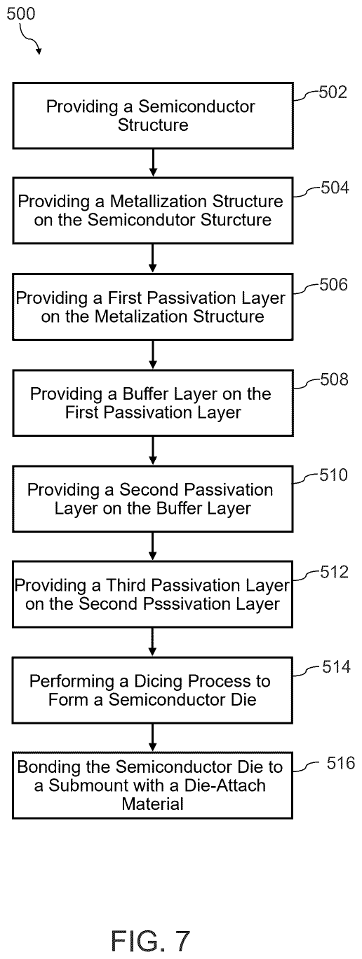

FIG. 7 depicts a flow chart diagram of an example method 500 according to example embodiments of the present disclosure. FIG. 7 depicts example process steps for purposes of illustration and discussion. Those having ordinary skill in the art, using the disclosures provided herein, will understand that the process steps of any of the methods described in the present disclosure may be adapted, modified, include steps not illustrated, omitted, and/or rearranged without deviating from the scope of the present disclosure.

At 502, the method 500 includes providing a semiconductor structure. The semiconductor structure may include an active region and an inactive region. In some examples, the semiconductor structure may be a wide bandgap semiconductor structure that includes a wide bandgap semiconductor, such as silicon carbide (SiC), a Group III-nitride (e.g., gallium nitride (GaN)), and/or the like.

At 504, the method 500 includes providing a metallization structure on the semiconductor structure. The metallization structure may be one or more of an electrode, an interconnect, or a runner for the semiconductor structure. In some examples, the metallization structure may include aluminum, an aluminum alloy (e.g., aluminum copper (AlCu)), and/or the like.

As described above (e.g., FIGS. 4A-6B), in some examples, a first metallization structure and a second metallization structure may be provided on the semiconductor structure. In some examples, the first metallization structure and the second metallization structure may be spaced apart from one another and may be located around at least a part of a peripheral portion of the power semiconductor device.

In some examples, the first metallization structure and the second metallization structure may each be peripheral runner structures for a power semiconductor device. For instance, the first metallization structure may be a source runner for the power semiconductor device and the second metallization structure may be a gate runner for the power semiconductor device. The power semiconductor device may further include a source pad and a gate pad. The first metallization structure and the source pad may form a source structure for the power semiconductor device. The second metallization structure and the gate pad may form a gate structure for the semiconductor device. In some examples, a silicide layer may be provided between the first metallization structure and the semiconductor structure to provide an ohmic contact for the semiconductor structure. In some examples, a gate polysilicon layer (e.g., gate finger) may be provided between the second metallization structure and the semiconductor structure.

At 506, the method 500 includes providing a first passivation layer on the metallization structure. In some examples, the first passivation layer includes a nitride, such as silicon nitride, and may have a thickness in a range of about 100 angstroms (Å) to about 2 kiloangstroms (kÅ). In some examples, at least a portion of the first passivation layer may contact the metallization structure. In some examples, the first passivation layer may have a uniform thickness across at least a portion of a width of the semiconductor structure. In other examples, the first passivation layer may have a non-uniform thickness across at least a portion of a width of the semiconductor structure.

At 508, the method 500 includes providing a buffer layer on the first passivation layer. The first passivation layer may form a seal between the buffer layer and the metallization structure and, thus, may reduce metal diffusion along an interface between the buffer layer and the metallization structure. In some examples, the buffer layer is an oxide buffer layer, and the oxide buffer layer may include silicon dioxide (SiO₂), hafnium dioxide (HfO₂), zirconium dioxide (ZrO₂), aluminum oxide (Al₂O₃), and/or the like.

At 510, the method 500 includes providing a second passivation layer on the buffer layer. The buffer layer may be a stress absorbing layer for the second passivation layer. The first passivation layer, the buffer layer, and the second passivation layer may form a passivation stack that extends across the inactive region of the semiconductor structure to a peripheral edge of the active region of the semiconductor structure. In some examples, the second passivation layer may include the same material as the first passivation layer, such as a nitride (e.g., silicon nitride (SiN_{X})). In some examples, the first passivation layer may have a lesser thickness relative to the second passivation layer. For instance, the first passivation layer may have a first thickness, and the second passivation layer may have a second thickness that is different than the first thickness. The second thickness may be greater than the first thickness. In some examples, the second thickness may be at least 1.5 times thicker than the first thickness, such as at least 3 times thicker than the first thickness, such as at least 5 times thicker than the first thickness.

At 512, the method 500 includes providing a third passivation layer on the second passivation layer. The third passivation layer may include a dielectric material, such as polyimide, silicon nitride (SiN_{X}), silicon oxide (SiO_{X}), and/or the like.

At 514, the method 500 includes performing a dicing process to form a semiconductor die. The semiconductor die may include the semiconductor structure, the metallization structure, the first passivation layer, the buffer layer, the second passivation layer, and the third passivation layer. In some examples, the first passivation layer may have a uniform thickness across at least a portion of a width of the semiconductor die. In other examples, the first passivation layer may have a non-uniform thickness across at least a portion of a width of the semiconductor die. Furthermore, the semiconductor die may include one of a silicon carbide-based metal-oxide-semiconductor field-effect transistor (MOSFET), a silicon carbide-based Schottky diode, or a Group-III nitride-based high electron mobility transistor (HEMT) device.

At 516, the method 500 includes bonding the semiconductor die to a submount with a die-attach material. Any suitable die-attach material may be used to couple the semiconductor die to the submount, such as metal sintering die-attach (e.g., silver (Ag) or copper (Cu)), conductive adhesive die-attach, and/or the like. The die-attach material may provide a thermal, mechanical, and/or electrical connection between the semiconductor die and the submount.

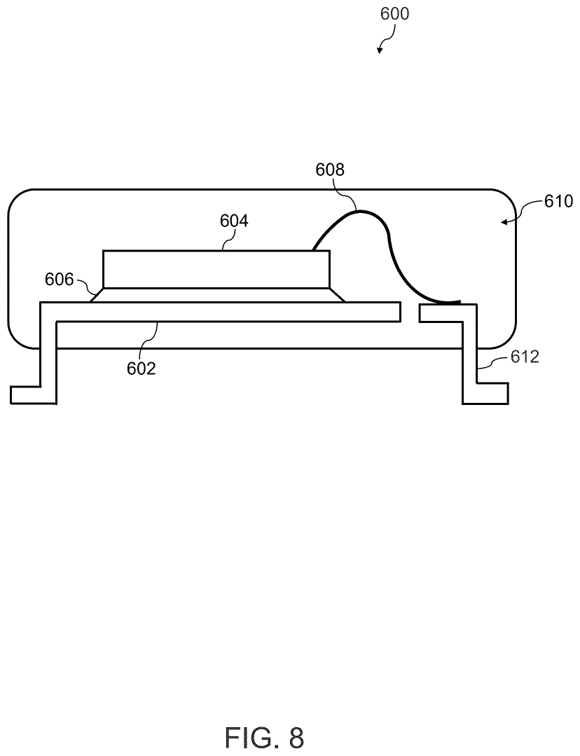

FIG. 8 depicts an example semiconductor package 600 of a semiconductor device according to example embodiments of the present disclosure. The semiconductor package 600 may be, for instance, a discrete power semiconductor device package. FIG. 8 is provided for purposes of illustration and discussion. Those having ordinary skill in the art, using the disclosures provided herein, will understand that aspects of the present disclosure may be used in a variety of devices and/or applications without deviating from the scope of the present disclosure. Furthermore, FIG. 8 is intended to represent structures for identification and description and is not intended to represent the structures to physical scale.

As shown, the semiconductor package 600 may include a conductive submount 602 (e.g., a patterned conductive substrate, lead frame, clip structure or other power substrate) on which a semiconductor die 604 containing one or more power devices (e.g., transistors, diodes, etc.) is attached using a die-attach material 606. It should be understood that the semiconductor die 604 may correspond to any of the semiconductor die disclosed herein and may be fabricated using any of the methods disclosed herein. It should be further understood that the power devices may correspond to any of the semiconductor devices disclosed herein and may be fabricated using any of the methods disclosed herein.

The die-attach material 606 may provide a thermal, mechanical, and electrical connection between the semiconductor die 604 and the conductive submount 602. In some examples, the semiconductor die 604 may also be connected to the conductive submount 602 using wire bonds 608. An encapsulating material 610 (e.g., epoxy mold compound (EMC)) may fill the space around the semiconductor die 604 and the submount 602, thereby forming a housing. The semiconductor package 600 may further include one or more connection structures, such as electrical leads 612, that extend outward from the housing (e.g., outward from the encapsulating material 610).

The semiconductor package 600 may include one or more metallization structures, such as any of the metallization structures disclosed herein. More particularly, the semiconductor die 604 may include one or more metallization structures, such as bonding pads. The bonding pads may be coupled to the one or more electrical leads 612 using the wire bonds 608. The wire bonds 608 may be aluminum and/or copper. The wire bonds 608 may have a thickness of about 15 mil to about 20 mil (e.g., about 381 μm to about 508 μm). As noted above, the bonding pads may have a thickness, for instance, of about 4 μm or less. A backside metallization layer on the semiconductor die 604 may be coupled to the submount 602 (e.g., lead frame) using, for instance, the die-attach material 606. The encapsulating material 610 may encapsulate the semiconductor die 604, including its metallization structures, wire bonds 608, submount 602, and other portions of the semiconductor package 600. In some examples, the encapsulating material 610 may directly contact the metallization structures (e.g., bonding pads, backside metallization layer, etc.) of the semiconductor package 600.

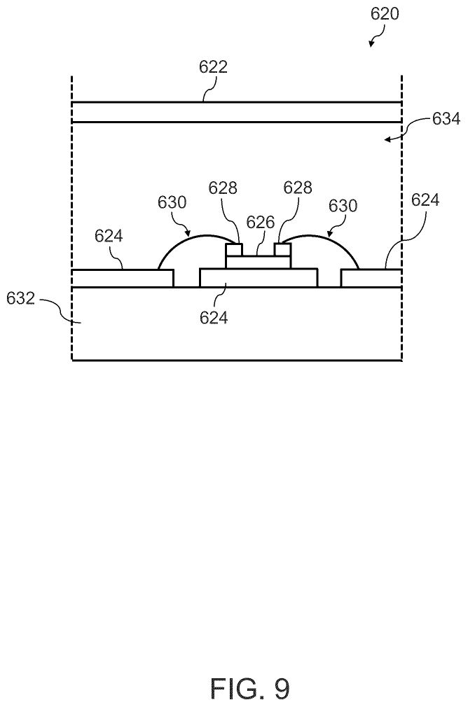

FIG. 9 depicts a cross-sectional view of an example semiconductor package of a semiconductor device 620 according to example embodiments of the present disclosure. The semiconductor device 620 of FIG. 9 is a portion of a power module. The semiconductor device 620 may correspond to any of the semiconductor devices disclosed herein and may be fabricated using any of the methods disclosed herein. FIG. 9 is intended to represent structures for identification and description and is not intended to represent the structures to physical scale. The semiconductor device 620 may include a housing 622. The semiconductor device 620 may include a conductive submount 624 (e.g., a patterned conductive submount) on which a semiconductor die 626 is mounted (e.g., using a die-attach material). It should be understood that the semiconductor die 626 may correspond to any of the semiconductor die disclosed herein and may be fabricated using any of the methods disclosed herein. For instance, the semiconductor die 626 may be mounted on submount 624 using a die-attach material that includes a sintered material, such as sintered silver and/or sintered copper. The semiconductor die 626 may include one or more metallization structures, such as bonding pads 628 and backside metallization structures (not shown) on an opposing side of the semiconductor die 626 from the bonding pads 628. It should be understood that the one or more metallization structures may correspond to any of the metallization structures described herein and may be provided using any of the methods and processes described herein. In some embodiments, the semiconductor die 626 may be connected to the conductive submount 624 using wire bonds 630. The conductive submount 624 may be mounted on a base layer 632 (e.g., an insulating layer). An inert gel 634 may fill the space between the semiconductor die 626 and the housing 622.

FIGS. 8-9 depict example semiconductor packages for purposes of illustration and discussion. Those of ordinary skill in the art, using the disclosures provided herein, will understand that different semiconductor package configurations may be used without deviating from the scope of the present disclosure.

Example aspects of the present disclosure are set forth below. Any of the below features or examples may be used in combination with any of the embodiments or features provided in the present disclosure.

In one aspect, the present disclosure provides an example power semiconductor device. In some implementations, the example power semiconductor device includes a semiconductor structure. In some implementations, the example power semiconductor device includes a metallization structure on the semiconductor structure. In some implementations, the example power semiconductor device includes a first passivation layer on the metallization structure, the first passivation having a first thickness. In some implementations, the example power semiconductor device includes a buffer layer on the first passivation layer. In some implementations, the example power semiconductor device includes a second passivation layer on the buffer layer, the second passivation layer comprising the same material as the first passivation layer, the second passivation layer having a second thickness that is different than the first thickness.

In some implementations of the example power semiconductor device, the example power semiconductor device further includes a polyimide layer directly contacting the second passivation layer.

In some implementations of the example power semiconductor device, the first passivation layer includes silicon nitride. In some implementations of the example power semiconductor device, the buffer layer includes silicon dioxide. In some implementations of the example power semiconductor device, the second passivation layer includes silicon nitride.

In some implementations of the example power semiconductor device, the first passivation layer has a lesser thickness relative to the second passivation layer.

In some implementations of the example power semiconductor device, the first passivation layer has a uniform thickness across at least a portion of a width of the power semiconductor device.

In some implementations of the example power semiconductor device, the second thickness is greater than the first thickness.

In some implementations of the example power semiconductor device, the second thickness is at least 1.5 times thicker than the first thickness.

In some implementations of the example power semiconductor device, the second thickness is at least 3 times thicker than the first thickness.

In some implementations of the example power semiconductor device, the first passivation layer has a thickness in a range of about 100 angstroms (Å) to about 2 kiloangstroms (kÅ).

In some implementations of the example power semiconductor device, the first passivation layer and the second passivation layer comprise a nitride.

In some implementations of the example power semiconductor device, the nitride is silicon nitride.

In some implementations of the example power semiconductor device, the buffer layer is a stress absorbing layer for the second passivation layer.

In some implementations of the example power semiconductor device, the buffer layer is an oxide buffer layer.

In some implementations of the example power semiconductor device, the oxide buffer layer includes silicon dioxide (SiO₂).

In some implementations of the example power semiconductor device, the oxide buffer layer includes one of hafnium dioxide (HfO₂), zirconium dioxide (ZrO₂), or aluminum oxide (Al₂O₃).

In some implementations of the example power semiconductor device, the first passivation layer reduces metal diffusion along an interface between the buffer layer and the metallization structure.

In some implementations of the example power semiconductor device, the first passivation layer, the buffer layer, and the second passivation layer form a passivation stack.

In some implementations of the example power semiconductor device, the semiconductor structure includes an active region and an inactive region, and the passivation stack extends across the inactive region to at least partially overlapping the active region.

In some implementations, the example power semiconductor device includes a second metallization structure on the semiconductor structure, and at least a portion of the first passivation layer is on the second metallization structure.

In some implementations of the example power semiconductor device, the first metallization structure is a source runner for the power semiconductor device.

In some implementations of the example power semiconductor device, the example power semiconductor device further includes a source pad, and the first metallization structure and the source pad form a source structure for the power semiconductor device.

In some implementations of the example power semiconductor device, the first metallization structure provides an ohmic contact with the semiconductor structure.

In some implementations of the example power semiconductor device, the ohmic contact further includes a silicide layer.

In some implementations of the example power semiconductor device, the second metallization structure is a gate runner for the power semiconductor device.

In some implementations of the example power semiconductor device, the example power semiconductor device further includes a gate pad, and the second metallization structure and the gate pad form a gate structure for the power semiconductor device.

In some implementations of the example power semiconductor device, the example power semiconductor device further includes a gate polysilicon layer between the second metallization structure and the semiconductor structure.

In some implementations of the example power semiconductor device, the gate polysilicon layer includes a gate finger.

In some implementations of the example power semiconductor device, the first metallization structure and the second metallization structure are each peripheral runner structures for the power semiconductor device, the first metallization structure and the second metallization structure being located around at least a part of a peripheral portion of the power semiconductor device.

In some implementations of the example power semiconductor device, the first metallization structure and the second metallization structure are spaced apart from one another.

In some implementations of the example power semiconductor device, at least a portion of the first passivation layer directly contacts the metallization structure.

In some implementations of the example power semiconductor device, the first passivation layer forms a seal between the buffer layer and the metallization structure.

In some implementations of the example power semiconductor device, the example power semiconductor device further includes a third passivation layer on the second passivation layer.

In some implementations of the example power semiconductor device, the third passivation layer is polyimide.

In some implementations of the example power semiconductor device, the metallization structure is one or more of an electrode, an interconnect, or a runner for the semiconductor structure.

In some implementations of the example power semiconductor device, the metallization structure includes an aluminum alloy.

In some implementations of the example power semiconductor device, the aluminum alloy is an aluminum-copper (AlCu) alloy.

In some implementations of the example power semiconductor device, the semiconductor structure includes a wide bandgap semiconductor.

In some implementations of the example power semiconductor device, the wide bandgap semiconductor is one of silicon carbide or a Group III-nitride.

In some implementations of the example power semiconductor device, the power semiconductor device includes one of a silicon carbide-based metal-oxide semiconductor field-effect transistor (MOSFET), a silicon carbide-based Schottky diode, or a Group-III nitride-based high electron mobility transistor (HEMT) device.

In another aspect, the present disclosure provides an example power semiconductor device package. In some implementations, the example power semiconductor device package includes a submount. In some implementations, the example power semiconductor device package includes a semiconductor die on the submount. In some implementations, the semiconductor die includes a metallization structure. In some implementations, the semiconductor die includes a first passivation layer on the metallization structure. In some implementations, the semiconductor die includes a buffer layer on the first passivation layer. In some implementations, the semiconductor die includes a second passivation layer on the buffer layer, the second passivation layer comprising the same material as the first passivation layer. In some implementations, the semiconductor die includes a polyimide layer directly on the second passivation layer.

In some implementations of the example power semiconductor device package, the first passivation layer includes silicon nitride. In some implementations of the example power semiconductor device package, the buffer layer includes silicon dioxide. In some implementations of the example power semiconductor device package, the second passivation layer includes silicon nitride.

In some implementations of the example power semiconductor device package, the first passivation layer has a first thickness and the second passivation layer has a second thickness, the second thickness being different than the first thickness.

In some implementations of the example power semiconductor device package, the first passivation layer has a lesser thickness relative to the second passivation layer.

In some implementations of the example power semiconductor device package, the first passivation layer has a uniform thickness across at least a portion of a width of the semiconductor die.

In some implementations of the example power semiconductor device package, the second thickness is greater than the first thickness.

In some implementations of the example power semiconductor device package, the second thickness is at least 1.5 times thicker than the first thickness.

In some implementations of the example power semiconductor device package, the second thickness is at least 3 times thicker than the first thickness.

In some implementations of the example power semiconductor device package, the first passivation layer has a thickness in a range of about 100 angstroms (Å) to about 2 kiloangstroms (kÅ).

In some implementations of the example power semiconductor device package, the first passivation layer and the second passivation layer comprise a nitride.

In some implementations of the example power semiconductor device package, the nitride is silicon nitride.

In some implementations of the example power semiconductor device package, the buffer layer is a stress absorbing layer for the second passivation layer.

In some implementations of the example power semiconductor device package, the buffer layer is an oxide buffer layer.

In some implementations of the example power semiconductor device package, the oxide buffer layer includes silicon dioxide (SiO₂).

In some implementations of the example power semiconductor device package, the oxide buffer layer includes one of hafnium dioxide (HfO₂), zirconium dioxide (ZrO₂), or aluminum oxide (Al₂O₃).

In some implementations of the example power semiconductor device package, the first passivation layer reduces metal diffusion along an interface between the buffer layer and the metallization structure.

In some implementations of the example power semiconductor device package, the first passivation layer, the buffer layer, and the second passivation layer form a passivation stack.

In some implementations of the example power semiconductor device package, the semiconductor die includes an active region and an inactive region, and the passivation stack extends across the inactive region to a peripheral edge of the active region.

In some implementations of the example power semiconductor device package, the semiconductor die includes a second metallization structure on the semiconductor structure, and at least a portion of the first passivation layer is on the second metallization structure.

In some implementations of the example power semiconductor device package, the first metallization structure is a source runner for the semiconductor die.

In some implementations of the example power semiconductor device package, the example power semiconductor device package further includes a source pad, and the first metallization structure and the source pad form a source structure for the power semiconductor device package.

In some implementations of the example power semiconductor device package, the example power semiconductor device package further includes an ohmic contact on the semiconductor structure.

In some implementations of the example power semiconductor device package, the ohmic contact includes a silicide layer between the first metallization structure and the semiconductor structure.

In some implementations of the example power semiconductor device package, the second metallization structure is a gate runner for the semiconductor die.

In some implementations of the example power semiconductor device package, the example power semiconductor device package further includes gate pad, and the second metallization structure and the gate pad form a gate structure for the power semiconductor device package.

In some implementations of the example power semiconductor device package, the semiconductor die further includes a gate polysilicon layer between the second metallization structure and the semiconductor structure.

In some implementations of the example power semiconductor device package, the gate polysilicon layer includes a gate finger.

In some implementations of the example power semiconductor device package, the first metallization structure and the second metallization structure are each peripheral runner structures for the semiconductor die, the first metallization structure and the second metallization structure being located around at least a part of a peripheral portion of the semiconductor die.

In some implementations of the example power semiconductor device package, the first metallization structure and the second metallization structure are spaced apart from one another.

In some implementations of the example power semiconductor device package, at least a portion of the first passivation layer directly contacts the metallization structure.

In some implementations of the example power semiconductor device package, the first passivation layer forms a seal between the buffer layer and the metallization structure.

In some implementations of the example power semiconductor device package, the metallization structure is one or more of an electrode, an interconnect, or a runner for the semiconductor die.

In some implementations of the example power semiconductor device package, the metallization structure includes an aluminum alloy.

In some implementations of the example power semiconductor device package, the semiconductor die includes a wide bandgap semiconductor structure comprising one of silicon carbide or a Group III-nitride.

In some implementations of the example power semiconductor device package, the semiconductor die includes one of a silicon carbide-based metal-oxide-semiconductor field-effect transistor (MOSFET), a silicon carbide-based Schottky diode, or a Group-III nitride-based high electron mobility transistor (HEMT) device.

In some implementations of the example power semiconductor device package, the example power semiconductor device package further includes a die-attach material coupling the semiconductor die to the submount.

In some implementations of the example power semiconductor device package, the example power semiconductor device package further includes an encapsulating portion.

In another aspect, the present disclosure provides an example method. In some implementations, the example method includes providing a semiconductor structure. In some implementations, the example method includes providing a metallization structure on the semiconductor structure. In some implementations, the example method includes providing a first passivation layer on the metallization structure, the first passivation layer having a first thickness. In some implementations, the example method includes providing a buffer layer on the first passivation layer. In some implementations, the example method includes providing a second passivation layer on the buffer layer, the second passivation layer comprising the same material as the first passivation layer, the second passivation layer having a second thickness that is different than the first thickness.

In some implementations of the example method, the first passivation layer includes silicon nitride. In some implementations of the example method, the buffer layer includes silicon dioxide. In some implementations of the example method, the second passivation layer includes silicon nitride.

In some implementations of the example method, the example method includes providing a third passivation layer on the second passivation layer.

In some implementations of the example method, providing the third passivation layer on the second passivation layer includes providing the polyimide layer directly on the second passivation layer.

In some implementations of the example method, the example method includes performing a dicing process to form a semiconductor die, the semiconductor die comprising the semiconductor structure, the metallization structure, the first passivation layer, the buffer layer, the second passivation layer, and the third passivation layer. In some implementations of the example method, the example method includes bonding the semiconductor die to a submount with a die-attach material.

In some implementations of the example method, the semiconductor die includes one of a silicon carbide-based metal-oxide-semiconductor field effect transistor (MOSFET), a silicon carbide-based Schottky diode, or a Group-III nitride-based high electron mobility transistor (HEMT) device.

In some implementations of the example method, the first passivation layer has a uniform thickness across at least a portion of a width of the semiconductor die.

In some implementations of the example method, the first passivation layer has a lesser thickness relative to the second passivation layer.

In some implementations of the example method, the second thickness is greater than the first thickness.

In some implementations of the example method, the second thickness is at least 1.5 times thicker than the first thickness.

In some implementations of the example method, the second thickness is at least 3 times thicker than the first thickness.

In some implementations of the example method, the first passivation layer has a thickness in a range of about 100 angstroms (Å) to about 2 kiloangstroms (kÅ).

In some implementations of the example method, the first passivation layer and the second passivation layer comprise a nitride.

In some implementations of the example method, the nitride is silicon nitride.

In some implementations of the example method, the buffer layer is a stress absorbing layer for the second passivation layer.

In some implementations of the example method, the buffer layer is an oxide buffer layer.

In some implementations of the example method, the oxide buffer layer includes silicon dioxide (SiO₂).

In some implementations of the example method, the oxide buffer layer includes one of hafnium dioxide (HfO₂), zirconium dioxide (ZrO₂), or aluminum oxide (Al₂O₃).

In some implementations of the example method, the first passivation layer reduces metal diffusion along an interface between the buffer layer and the metallization structure.

In some implementations of the example method, the first passivation layer, the buffer layer, and the second passivation layer form a passivation stack.

In some implementations of the example method, the semiconductor structure includes an active region and an inactive region, and the passivation stack extends across the inactive region to a peripheral edge of the active region.

In some implementations, the example method includes providing a second metallization structure on the semiconductor structure, and at least a portion of the first passivation layer is provided on the second metallization structure.

In some implementations of the example method, the first metallization structure is a source runner for a power semiconductor device.

In some implementations of the example method, the power semiconductor device includes a source pad, and the first metallization structure and the source pad form a source structure for the power semiconductor device.

In some implementations of the example method, the example method includes providing an ohmic contact on the semiconductor structure.

In some implementations of the example method, providing the ohmic contact on the semiconductor structure includes providing a silicide layer between the first metallization structure and the semiconductor structure.

In some implementations of the example method, the second metallization structure is a gate runner for a power semiconductor device.

In some implementations of the example method, the power semiconductor device includes a gate pad, and the second metallization structure and the gate pad form a gate structure for the power semiconductor device.

In some implementations of the example method, the example method includes providing a gate polysilicon layer between the second metallization structure and the semiconductor structure.

In some implementations of the example method, the gate polysilicon layer comprises a gate finger.

In some implementations of the example method, the first metallization structure and the second metallization structure are each peripheral runner structures for a power semiconductor device, the first metallization structure and the second metallization structure being located around at least a part of a peripheral portion of the power semiconductor device.

In some implementations of the example method, the first metallization structure and the second metallization structure are spaced apart from one another.

In some implementations of the example method, at least a portion of the first passivation layer contacts the metallization structure.

In some implementations of the example method, the first passivation layer forms a seal between the buffer layer and the metallization structure.

In some implementations of the example method, the metallization structure is one or more of an electrode, an interconnect, or a runner for the semiconductor structure.

In some implementations of the example method, the metallization structure comprises an aluminum alloy.

In some implementations of the example method, the semiconductor structure comprises a wide bandgap semiconductor, the wide bandgap semiconductor being one of silicon carbide or a Group III-nitride.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A power semiconductor device, comprising:
a semiconductor structure;
a metallization structure on the semiconductor structure;
a first passivation layer on the metallization structure, the first passivation having a first thickness;
a buffer layer on the first passivation layer; and
a second passivation layer on the buffer layer, the second passivation layer comprising the same material as the first passivation layer, the second passivation layer having a second thickness that is different than the first thickness.

2. The power semiconductor device of claim 1, further comprising a polyimide layer directly contacting the second passivation layer.

3. The power semiconductor device of claim 1, wherein the first passivation layer has a lesser thickness relative to the second passivation layer.

4. The power semiconductor device of claim 1, wherein the first passivation layer and the second passivation layer comprise a nitride.

5. The power semiconductor device of claim 1, wherein the buffer layer is an oxide buffer layer, the oxide buffer layer comprising one of silicon dioxide (SiO₂), hafnium dioxide (HfO₂), zirconium dioxide (ZrO₂), or aluminum oxide (Al₂O₃).

6. The power semiconductor device of claim 1, wherein at least a portion of the first passivation layer directly contacts the metallization structure.

7. The power semiconductor device of claim 1, wherein the metallization structure is one or more of an electrode, an interconnect, or a runner for the semiconductor structure.

8. The power semiconductor device of claim 1, wherein the power semiconductor device comprises one of a silicon carbide-based metal-oxide-semiconductor field-effect transistor (MOSFET), a silicon carbide-based Schottky diode, or a Group-III nitride-based high electron mobility transistor (HEMT) device.

9. A power semiconductor device package, comprising:
a submount; and
a semiconductor die on the submount, the semiconductor die comprising:
a metallization structure;
a first passivation layer on the metallization structure;
a buffer layer on the first passivation layer;
a second passivation layer on the buffer layer, the second passivation layer comprising the same material as the first passivation layer; and
a polyimide layer directly on the second passivation layer.

10. The power semiconductor device package of claim 9, wherein:
the first passivation layer comprises silicon nitride;
the buffer layer comprises silicon dioxide; and
the second passivation layer comprises silicon nitride,
wherein the first passivation layer has a first thickness and the second passivation layer has a second thickness, the second thickness being different than the first thickness.

11. The power semiconductor device package of claim 9, wherein:
the buffer layer is a stress absorbing layer for the second passivation layer; and
the first passivation layer reduces metal diffusion along an interface between the buffer layer and the metallization structure.

12. The power semiconductor device package of claim 9, wherein the metallization structure is a first metallization structure on a semiconductor structure of the semiconductor die, the semiconductor die further comprising:
a second metallization structure on the semiconductor structure, wherein at least a portion of the first passivation layer is on the second metallization structure, and wherein the first metallization structure is a source runner for the semiconductor die and the second metallization structure is a gate runner for the semiconductor die.

13. The power semiconductor device package of claim 12, further comprising an ohmic contact on the semiconductor structure, the ohmic contact comprising a silicide layer between the first metallization structure and the semiconductor structure.

14. The power semiconductor device package of claim 12, wherein the first metallization structure and the second metallization structure are spaced apart from one another and are each peripheral runner structures for the semiconductor die, the first metallization structure and the second metallization structure being located around at least a part of a peripheral portion of the semiconductor die.

15. The power semiconductor device package of claim 9, wherein the first passivation layer forms a seal between the buffer layer and the metallization structure.

16. The power semiconductor device package of claim 9, wherein the semiconductor die comprises a wide bandgap semiconductor structure comprising one of silicon carbide or a Group III-nitride.

17. A method, comprising:
providing a semiconductor structure;
providing a metallization structure on the semiconductor structure;
providing a first passivation layer on the metallization structure, the first passivation layer having a first thickness;
providing a buffer layer on the first passivation layer; and
providing a second passivation layer on the buffer layer, the second passivation layer comprising the same material as the first passivation layer, the second passivation layer having a second thickness that is different than the first thickness.

18. The method of claim 17, further comprising:
providing a third passivation layer directly on the second passivation layer,
wherein the third passivation layer is a polyimide layer.

19. The method of claim 18, further comprising:
performing a dicing process to form a semiconductor die, the semiconductor die comprising the semiconductor structure, the metallization structure, the first passivation layer, the buffer layer, the second passivation layer, and the third passivation layer; and
bonding the semiconductor die to a submount with a die-attach material.

20. The method of claim 17, wherein the metallization structure is a first metallization structure, the method further comprising:
providing a second metallization structure on the semiconductor structure, wherein at least a portion of the first passivation layer is provided on the second metallization structure.
